(19) United States
(12) Patent Application Publication
(10) Pub. No.: US 2026/0255936 A1
(43) Pub. Date: Aug. 27, 2026

(54) SEMICONDUCTOR PACKAGE AND METHOD FOR FORMING THE SAME

(71) Applicant: TAIWAN SEMICONDUCTOR MANUFACTURING COMPANY LTD., HSINCHU (TW)

(72) Inventors: TZU JUNG TIEN, HSINCHU COUNTY (TW); JEN-YUAN CHANG, HSINCHU CITY (TW)

(21) Appl. No.: 19/062,075

(22) Filed: Feb. 25, 2025

(51) Int. Cl. H10W 20/00; G02B 6/125; H10W 74/10; H10W 90/00

(52) U.S. Cl. CPC H10W 20/033; G02B 6/125; H10W 20/056; H10W 20/081; H10W 74/121; H10W 90/00

(57) ABSTRACT

A semiconductor package and a method for forming the same are provided. The method includes the following steps: providing a photonic die comprising a plurality of optical waveguides; electrically connecting the photonic die with an electronic die; and forming a plurality of optical coupling layers substantially aligned with the optical waveguides and having a spacing increasing away from the photonic die.

### BACKGROUND

Electrical signaling and processing are one technique for signal transmission and processing. Optical signaling and processing have been used in increasingly more applications in recent year. Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating optical components and electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a top view of a semiconductor package according to one or more embodiments of the present disclosure.

FIG. 1B is a cross-sectional view of a semiconductor package according to one or more embodiments of the present disclosure.

FIG. 1C is a cross-sectional view of a semiconductor package according to one or more embodiments of the present disclosure.

FIG. 1D is a cross-sectional view of a semiconductor package according to one or more embodiments of the present disclosure.

FIG. 1E is a cross-sectional view of a semiconductor package according to one or more embodiments of the present disclosure.

FIG. 2A is a top view of a semiconductor package according to one or more embodiments of the present disclosure.

FIG. 2B is a cross-sectional view of a semiconductor package according to one or more embodiments of the present disclosure.

FIG. 2C is a cross-sectional view of a semiconductor package according to one or more embodiments of the present disclosure.

FIG. 2D is a top view of a semiconductor package according to one or more embodiments of the present disclosure.

FIG. 2E is a cross-sectional view of a semiconductor package according to one or more embodiments of the present disclosure.

FIG. 3A is a top view of a semiconductor package according to one or more embodiments of the present disclosure.

FIG. 3B is a cross-sectional view of a semiconductor package according to one or more embodiments of the present disclosure.

FIG. 3C is a cross-sectional view of a semiconductor package according to one or more embodiments of the present disclosure.

FIG. 4A is a top view of a semiconductor package according to one or more embodiments of the present disclosure.

FIG. 4B is a cross-sectional view of a semiconductor package according to one or more embodiments of the present disclosure.

FIG. 5A is a top view of a semiconductor package according to one or more embodiments of the present disclosure.

FIG. 5B is a cross-sectional view of a semiconductor package according to one or more embodiments of the present disclosure.

FIG. 5C is a cross-sectional view of a semiconductor package according to one or more embodiments of the present disclosure.

FIGS. 6A to 6F are schematic drawings illustrating a method for forming a semiconductor package according to one or more embodiments of the present disclosure.

FIGS. 7A to 7H are schematic drawings illustrating a method for forming a semiconductor package according to one or more embodiments of the present disclosure.

FIGS. 8A to 8C are schematic drawings illustrating a method for forming a semiconductor package according to one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” "on" and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as "first," "second" and "third" describe various elements, components, regions, layers and/or sections, but these elements, components, regions, layers and/or sections should not be limited by these terms. These terms may be only used to distinguish one element, component, region, layer or section from another. The terms such as "first," "second" and "third" when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms "substantially," "approximately" or “about” generally mean within a value or range that can be contemplated by people having ordinary skill in the art. Alternatively, the terms "substantially," "approximately" or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms "substantially," "approximately" or "about." Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Embodiments of the present disclosure discuss a semiconductor package including an optical redistribution structure integrated with a photonic die and an electronic die to form an integrated silicon photonic structure. The relatively small-pitch optical I/O terminals of the photonic die of the integrated silicon photonic structure can be directly optically coupled to and fan-out to the relatively large-pitch optical I/O terminals of an optical module through the optical redistribution structure. Therefore, the pitch of the optical I/O terminals of the photonic die can remain relatively small without being enlarged to match the relatively large pitch of the optical I/O terminals of the optical module, and thus the number of the optical I/O terminals of the photonic die that optically couple to the optical module can be increased.

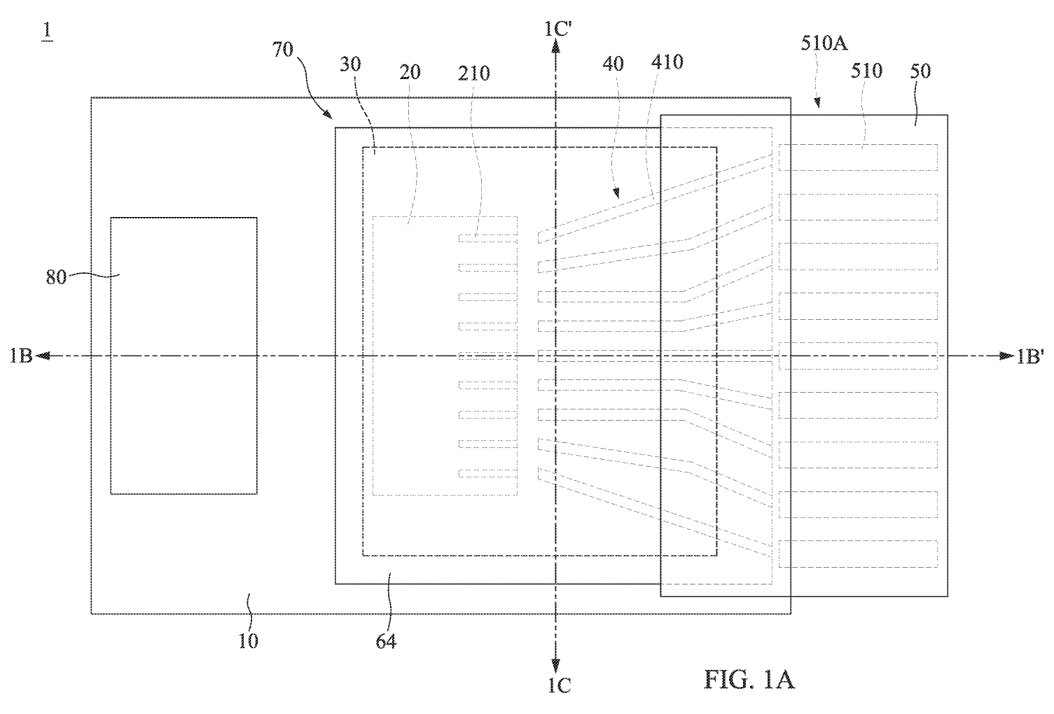

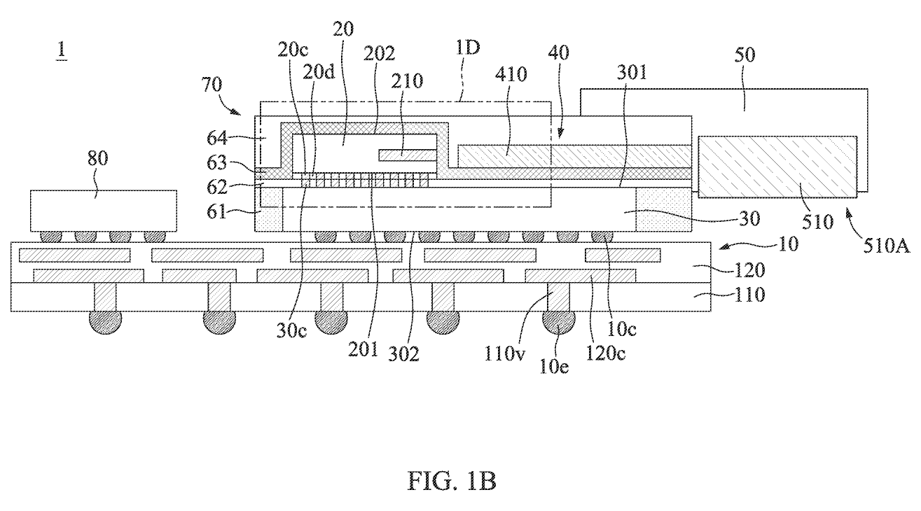

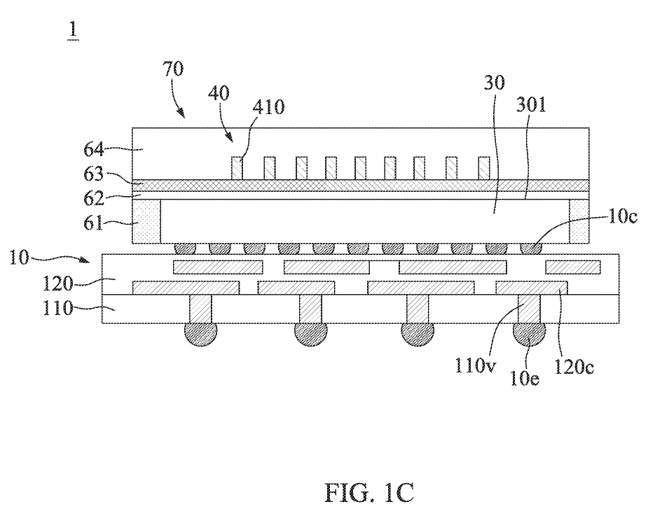

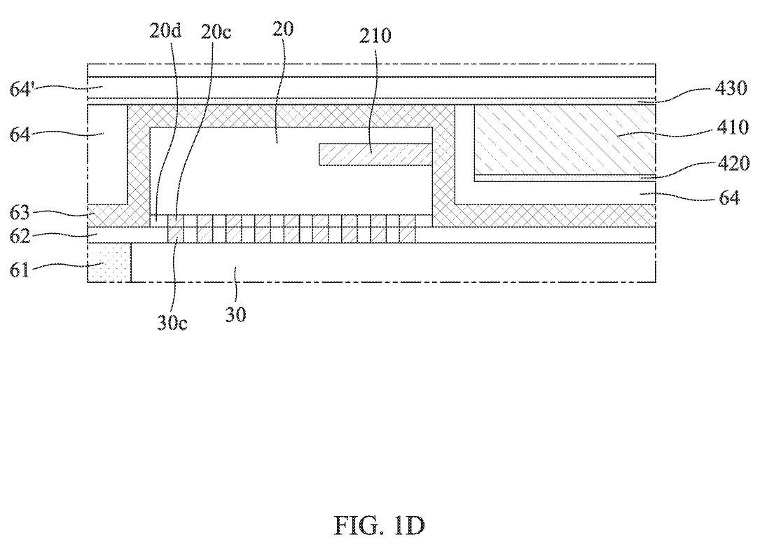

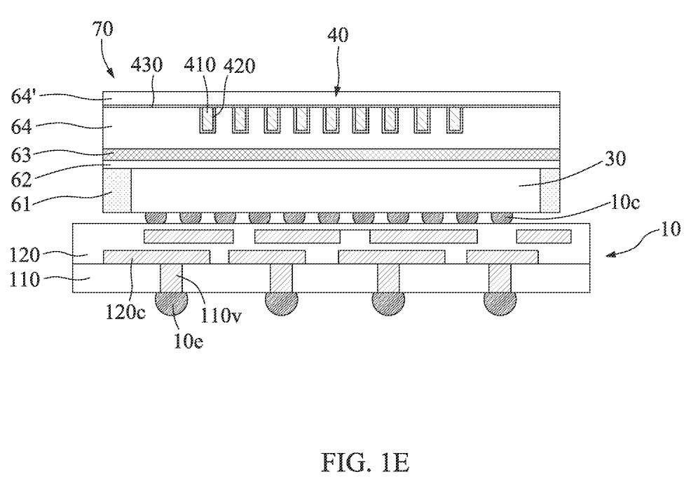

FIG. 1A is a top view of a semiconductor package 1 according to one or more embodiments of the present disclosure. FIG. 1B is a cross-sectional view of a semiconductor package 1 according to one or more embodiments of the present disclosure. FIG. 1C is a cross-sectional view of a semiconductor package 1 according to one or more embodiments of the present disclosure. In some embodiments, FIG. 1B is a cross-section along a line 1B-1B’ in FIG. 1A, and FIG. 1C is a cross-section along a line 1C-1C’ in FIG. 1A.

The semiconductor package 1 may include a substrate 10, electrical connectors 10c and 10e, a photonic die 20, an electronic die 30, an optical redistribution structure 40, a holder 50, an optical module 510A, dielectric layers 61-64, and a semiconductor chip 80. The semiconductor package 1 may be or include a silicon photonic device.

The substrate 10 may be or include a package component. In some embodiments, the substrate 10 is or includes a package substrate, a printed circuit board (PCB), a package, or the like. The substrate 10 may have a top surface for supporting at least the photonic die 20, the electronic die 30, and the optical redistribution structure 40. In some embodiments, the substrate 10 includes an interposer and a redistribution layer on the interposer. In some embodiments, the redistribution layer includes a dielectric layer 120 and conductive layers 120c in the dielectric layer 120, and the interposer includes a semiconductor layer 110 and conductive vias 110v (e.g., through silicon vias) in the semiconductor layer 110.

The electrical connectors 10c and 10e may be electrically connected to the substrate 10. In some embodiments, the electrical connectors 10c and 10e include metal pillars and solder regions, which may be used for solder bonding. In some embodiments, the electrical connectors 10c and 10e include solder balls.

The photonic die 20 may be disposed over the top surface of the substrate 10. The photonic die 20 may be or include a photonic integrated circuit (PIC) die. In some embodiments, the photonic die 20 includes optical waveguides 210, conductive features 20c, and a dielectric layer 20d. The optical waveguides 210 may include or be formed of silicon nitride, silicon oxynitride, polymer, or other suitable waveguide materials. The conductive features 20c may include conductive pads, conductive pillars, or the like. The photonic die 20 may further include other active or passive components, such as laser diodes, optical signal splitters, or other types of photonic structures or devices. The photonic die 20 may have an active surface 201 and a back surface 202.

The electronic die 30 may be disposed between the substrate 10 and the photonic die 20. In some embodiments, the electronic die 30 is electrically connected to the photonic die 20. The electronic die 30 may be or include an electronic integrated circuit (EIC) die. In some embodiments, the electronic die 30 includes electrical connectors 30c. In some embodiments, the electronic die 30 includes electronic integrated circuits, e.g., controllers, drivers, amplifiers, the like, or combinations thereof. The electrical connectors 30c may include conductive pads, conductive pillars, or the like. In some embodiments, the electronic die 30 is bonded to the photonic die 20 through hybrid bonding. In some embodiments, the dielectric layer 62 is formed on a surface of the electronic die 30, and the electrical connectors 30c are formed within the dielectric layer 62. In some embodiments, the dielectric layer 62 is bonded to the dielectric layer 20d through fusion bonding, and the electrical connectors 30c are bonded to the conductive features 20c through metal-to-metal direct bonding. The dielectric layers 62 and 20d may include silicon oxide, silicon oxynitride, or the like. The electronic die 30 may have an active surface 301 and a back surface 302.

The optical module 510A may be configured to optically couple to the photonic die 20. In some embodiments, the optical module 510A includes optical fibers 510 configured to optically couple to the optical waveguides 210 of the photonic die 20.

The optical redistribution structure 40 may be configured to optically couple to the photonic die 20. In some embodiments, the optical redistribution structure 40 is configured to optically couple the photonic die 20 to the optical module 510A.

In some embodiments, the optical redistribution structure 40 includes a plurality of optical coupling layers 410. In some embodiments, the optical coupling layers 410 are over the dielectric layer 63 and substantially aligned with optical waveguides 210 of the photonic die 20. In some embodiments, the optical waveguides 210 are configured to optically couple to the optical module 510A through the optical coupling layers 410. In some embodiments, at least two of the optical coupling layers 410 include curved profiles that bend toward different directions and extend tilt away from each other. In some embodiments, the optical coupling layers 410 collectively construct an optical fan-out structure.

In some embodiments, the optical coupling layers 410 may include core layers and cladding layers covering the core layers. The refractive index of the cladding layers are smaller than the refractive index of the core layers to ensure that the core layers have high internal reflections, such that lights or optical signals transmitted by the optical coupling layers can be substantially confined within the optical coupling layers 410.

In some embodiments, the optical coupling layers 410 have a pitch increasing away from the photonic die 20. In some embodiments, the pitch of the optical coupling layers 410 increases from the photonic die 20 toward the optical module 510A. In some embodiments, a minimum pitch of the optical coupling layers 410 is substantially equal to a pitch of the optical waveguides 210. In some embodiments, a maximum pitch of the optical coupling layers 410 is substantially equal to a pitch of the optical fibers 510.

In some embodiments, the optical coupling layers 410 have a spacing increasing away from the photonic die 20. In some embodiments, the spacing of the optical coupling layers 410 increases from the photonic die 20 toward the optical module 510A. In some embodiments, a minimum spacing of the optical coupling layers 410 is substantially equal to a spacing of the optical waveguides 210. In some embodiments, a maximum spacing of the optical coupling layers 410 is substantially equal to a spacing of the optical fibers 510.

In some embodiments, the optical coupling layers 410 have substantially constant widths. In some embodiments, the width of the optical coupling layers 410 is greater than a width of the optical waveguides 210. In some embodiments, the width of the optical coupling layers 410 is less than a width of optical fibers 510 of the optical module 510A. In some embodiments, the width of the optical coupling layers 410 may increase from the photonic die 20 toward the optical module 510A.

In some embodiments, the dielectric layer 61 covers or surrounds the electronic die 30. The dielectric layer 61 may include silicon oxide, silicon oxynitride, silicon nitride, a molding compound, or the like. In some embodiments, the dielectric layer 61 includes a molding compound. In some embodiments, a top surface of the dielectric layer 61 is substantially coplanar with a top surface (e.g., the active surface 301) of the electronic die 30. In some embodiments, the dielectric layer 61 may be or include a planarized layer or a gap-fill dielectric that serves to provide a substantially planarized surface for supporting the optical redistribution structure 40. The dielectric layer 61 combined with the electronic die 30 may provide a planarized supporting surface for disposing the optical redistribution structure 40.

In some embodiments, the dielectric layer 62 is formed over the entire surface of the electronic die 30 and the dielectric layer 61. In some embodiments, the electrical connectors 30c of the electronic die 30 are within the dielectric layer 62, and top surfaces of the electrical connectors 30c are substantially coplanar with a top surface of the dielectric layer 62. In some embodiments, the dielectric layer 62 is bonded to the dielectric layer 20d of the photonic die 20 through fusion bonding, and the electrical connectors 30c of the electronic die 30 are bonded to the conductive features 20c of the photonic die 20 through metal-to-metal direct bonding, so as to connect the photonic die 20 to the electronic die 30 through hybrid bonding. The dielectric layer 62 may include silicon oxide, silicon oxynitride, or the like.

In some embodiments, the dielectric layer 63 is over the photonic die 20 and the electronic die 30. In some embodiments, the dielectric layer 63 covers the optical redistribution structure 40 and the photonic die 20. In some embodiments, the dielectric layer 63 may be or include a protective layer that serves to protect the photonic die 20 and the optical waveguides 210 from damages. In some embodiments, the dielectric layer 63 (or the protective layer) is between the dielectric layer 64 and the photonic die 20. The dielectric layer 63 may include silicon oxide, silicon oxynitride, silicon nitride, a molding compound, or the like. In some embodiments, the dielectric layer 63 includes silicon nitride.

In some embodiments, the dielectric layer 64 is over the photonic die 20, the electronic die 30, and the dielectric layer 63. In some embodiments, the dielectric layer 64 covers the photonic die 20, the electronic die 30, the optical redistribution structure 40, and the dielectric layer 63. In some embodiments, the dielectric layer 64 covers the optical coupling layers 410 and the optical waveguides 210. In some embodiments, the dielectric layer 64 may be or includes a gap-fill dielectric that fills gaps between the photonic die 20 and the optical redistribution structure 40. The dielectric layer 64 may include silicon oxide, silicon oxynitride, silicon nitride, a molding compound, or the like. In some embodiments, the dielectric layer 64 includes silicon oxide.

In some embodiments, the photonic die 20 is hybrid-bonded to the electronic die 30, and the optical redistribution structure 40 is formed on the electronic die 30 and adjacent to the photonic die 20. In some embodiments, the dielectric layers 61, 62, 63, and 64 cover or encapsulate the photonic die 20, the electronic die 30, and the optical redistribution structure 40 (or the optical fan-out structure) to form a combo die 70 (or an integrated silicon photonic device) that integrates the optical redistribution structure 40 into the silicon photonic structure including the photonic die 20 and the electronic die 30.

The holder 50 may fix the relative position between the optical module 510A and the photonic die 20. In some embodiments, the holder 50 may include a frame to accommodate and fasten the optical module 510A, an adhesive structure to attach to the optical module 510A, or any suitable holding structure that may fix the relative position between the optical module 510A and the photonic die 20 so as to allow the optical fibers 510 to maintain at fixed positions to align with the optical waveguides 210.

The semiconductor chip 80 may be electrically connected to the substrate 10. In some embodiments, the semiconductor chip 80 is electrically connected to the substrate 10 through the electrical connectors 10c. In some embodiments, the semiconductor chip 80 is configured to exchange electrical signals with the photonic die 20. The semiconductor chip 80 may be or include a logic IC die, a memory die, an analog IC die, an application-specific IC (ASIC) die, or the like.

When optical signals are transmitted from the optical module 510A directly to the optical waveguides 210 of the photonic die 20, since the pitch of the optical fibers 510 of the optical module 510A is larger than the pitch of the optical waveguides 210 of the photonic die 20, a larger device area is required to optically couple to the optical fibers 510. Alternatively, if the device area for optically coupling to the optical fibers 510 is limited to the relatively small coupling area of the photonic die 20, the number of the optical fibers 510 is reduced to match the relatively small coupling area of the photonic die, thereby the number of the optical I/O terminals is reduced.

According to some embodiments of the present disclosure, with the optical fan-out structure (e.g., the optical redistribution structure 40) integrated into the silicon photonic structure, the relatively small-pitch optical I/O terminals of the photonic die 20 of the integrated silicon photonic structure can be directly optically coupled to and fan-out to the relatively large-pitch optical I/O terminals of the optical module 510A. Therefore, the pitch of the optical I/O terminals of the photonic die 20 can remain relatively small without being enlarged to match the relatively large pitch of the optical I/O terminals of the optical module 510A, and thus the number of the optical I/O terminals of the photonic die 20 that optically couple to the optical module 510A can be increased.

In addition, according to some embodiments of the present disclosure, the optical redistribution structure 40 and the photonic die 20 are covered by the dielectric layers 63 and 64. Therefore, the optical redistribution structure 40 and the photonic die 20 can be protected, and the relative position between the optical redistribution structure 40 and the photonic die 20 can be fixed, so as to ensure accurate and stable optical alignment between the optical waveguides 210 and the optical coupling layers 410.

Moreover, according to some embodiments of the present disclosure, the holder 50 may fix the relative position between the optical module 510A and the photonic die 20. Therefore, the optical fibers 510 can maintain at fixed positions to align with the optical waveguides 210, so as to ensure accurate and stable optical alignment between the optical waveguides 210 and the optical fibers 510.

FIG. 1D is a cross-sectional view of a semiconductor package according to one or more embodiments of the present disclosure. FIG. 1E is a cross-sectional view of a semiconductor package according to one or more embodiments of the present disclosure. In some embodiments, FIG. 1D is a cross-sectional view of a portion 1D of the semiconductor package 1 in FIG. 1A, and FIG. 1E is a cross-section of the portion 1D along the line 1C-1C’.

In some embodiments, the semiconductor package 1 may further include reflective liners 420, a reflective cap layer 430, and a dielectric layer 64’.

In some embodiments, the reflective liners 420 are between the optical coupling layers 410 and the dielectric layer 64. In some embodiments, each of the reflective liners 420 covers sidewalls and a bottom surface of each of the optical coupling layers 410. In some embodiments, the reflective liners 420 are free from covering end surfaces (or coupling surfaces) of the optical coupling layers 410. The reflective liners 420 may include Ta, TaN, Ti, TiN, or a combination thereof.

In some embodiments, the reflective cap layer 430 is over and contacting the dielectric layers 63 and 64 and the optical coupling layers 410. In some embodiments, the reflective cap layer 430 is between the dielectric layers 64 and 64’. In some embodiments, the dielectric layer 64’ is on the dielectric layer 64 and the optical coupling layers 410. The dielectric layer 64’ may include silicon oxide, silicon oxynitride, silicon nitride, a molding compound, or the like. In some embodiments, the dielectric layer 64’ includes silicon oxide. The reflective cap layer 430 may include Ta, TaN, Ti, TiN, or a combination thereof. The optical coupling layers 410 covered by the reflective liners 420 and the reflective cap layer 430 may include polysilicon, polymer, silicon oxide, silicon oxynitride, or any suitable material.

According to some embodiments of the present disclosure, the optical coupling layers 410 are manufactured by forming trenches, e.g., by etching, in the dielectric layer 64 followed by filling an optical coupling material in the trenches. Therefore, the profiles of the trenches can be made with various different shapes (e.g., curved strips bending toward various directions) according to applications, thus the optical coupling layers 410 can fan-out the optical coupling paths effectively within a limited area.

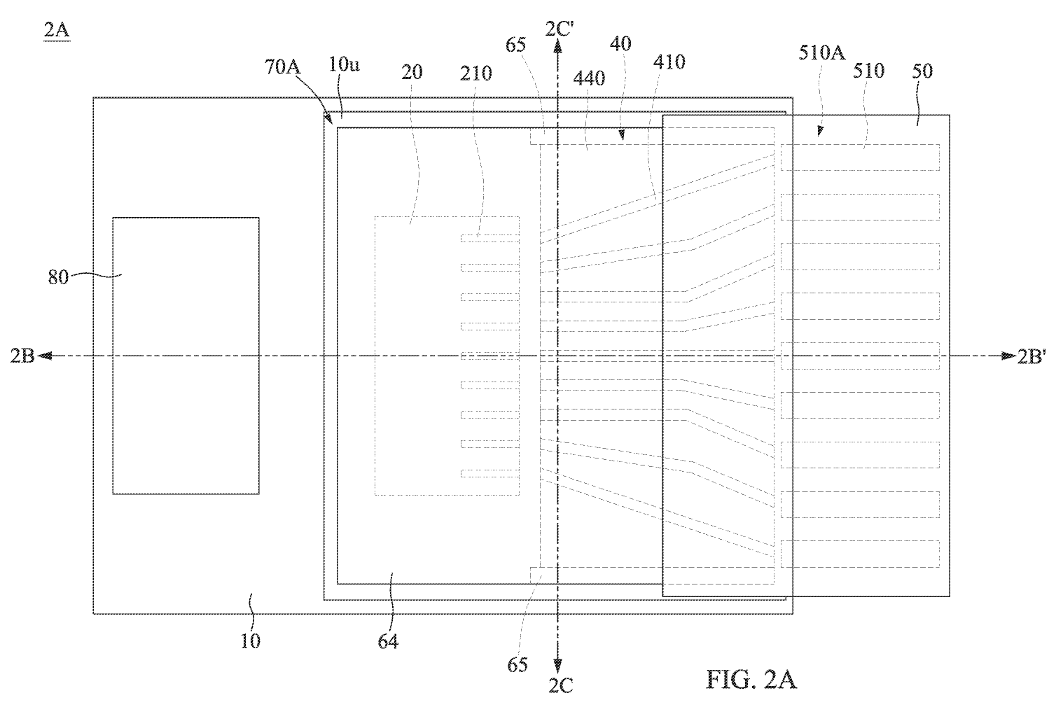

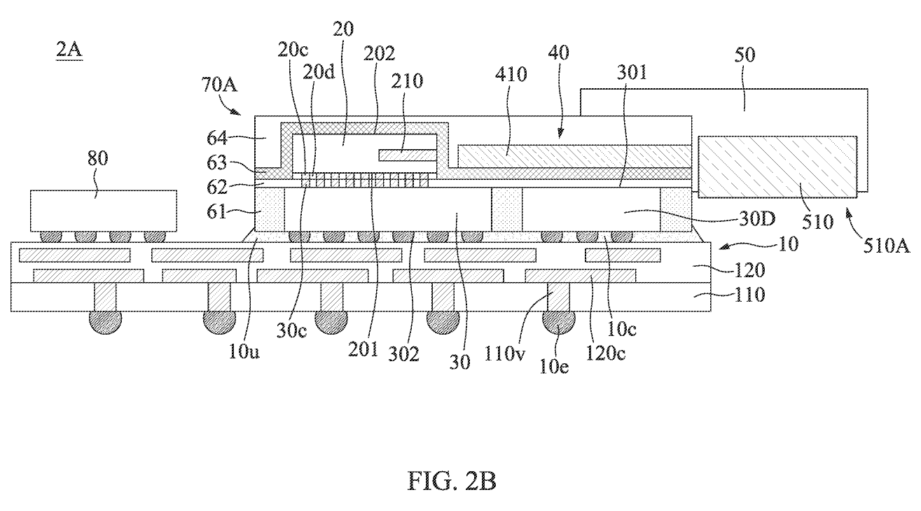

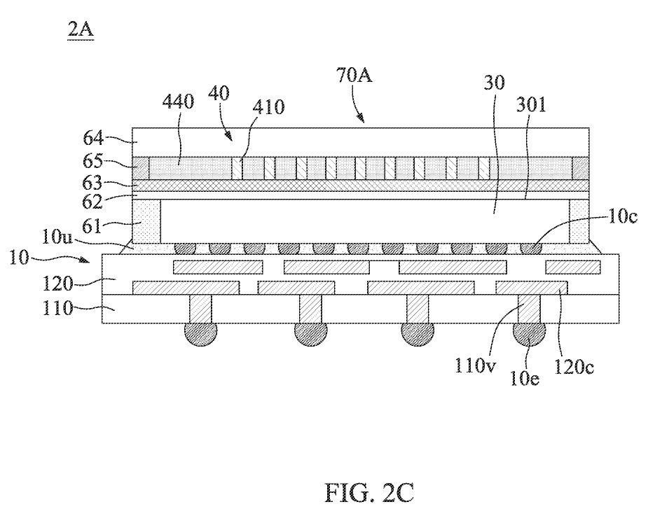

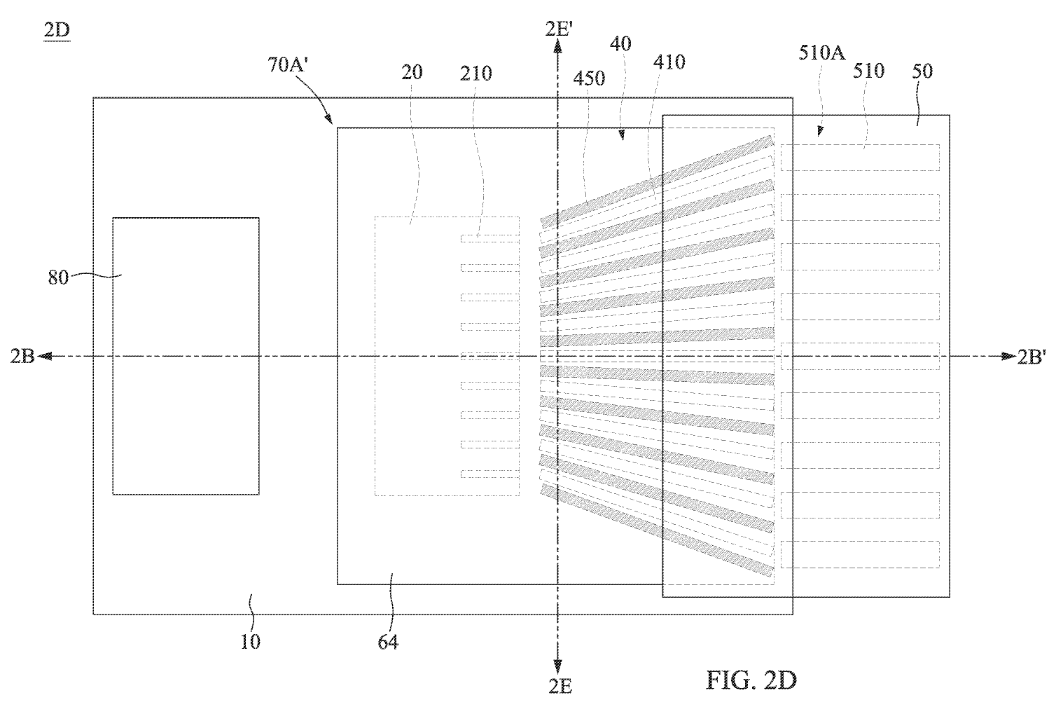

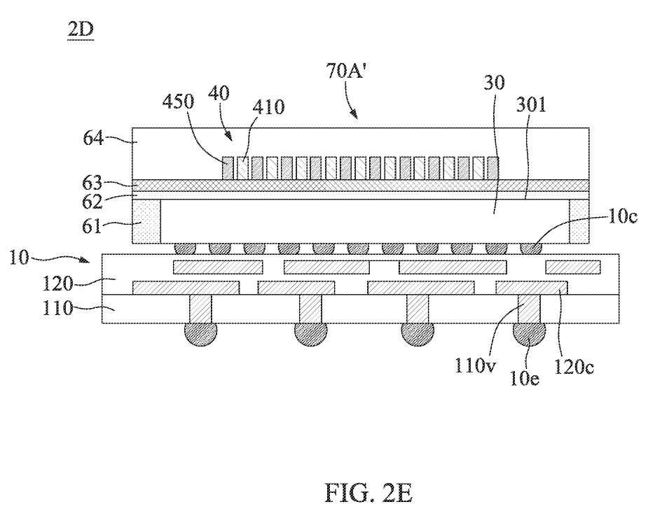

FIG. 2A is a top view of a semiconductor package 2A according to one or more embodiments of the present disclosure. FIG. 2B is a cross-sectional view of a semiconductor package 2A according to one or more embodiments of the present disclosure. FIG. 2C is a cross-sectional view of a semiconductor package 2A according to one or more embodiments of the present disclosure. In some embodiments, FIG. 2B is a cross-section along a line 2B-2B’ in FIG. 2A, and FIG. 2C is a cross-section along a line 2C-2C’ in FIG. 2A. The semiconductor package 2A illustrated in FIGS. 2A-2C is similar to the semiconductor package 1 illustrated in FIGS. 1A-1C, and the differences therebetween are described as follows.

In some embodiments, the optical redistribution structure 40 includes an optical fan-out die, which includes a cladding base 440 and the optical coupling layers 410 formed within the cladding base 440. In some embodiments, the dielectric layer 64 covers the optical fan-out die.

In some embodiments, referring to FIGS. 2A and 2C, the semiconductor package 2A further includes dummy dies 65. In some embodiments, the optical fan-out die (i.e., the optical redistribution structure 40) is interposed between the dummy dies 65. The dummy die 65 may serve to define a space for disposing the optical fan-out die. The dummy dies 65 may be or include semiconductor wafers, e.g., silicon substrates. In some embodiments, the dielectric layer 64 covers the optical fan-out die and the dummy dies 65.

In some embodiments, referring to FIG. 2B, the semiconductor package 2A further includes a dummy die 30D. In some embodiments, the dummy die 30D is covered or surrounded by the dielectric layer 61. The dielectric layer 61 combined with the electronic die 30 and the dummy die 30D may provide a planarized supporting surface for disposing the optical fan-out die. The dummy dies 30D may be or include a semiconductor wafer, e.g., a silicon substrate.

In some embodiments, the dielectric layers 61, 62, 63, and 64 cover or encapsulate the photonic die 20, the electronic die 30, the dummy dies 65 and 30D, and the optical redistribution structure 40 (or the optical fan-out structure) to form a combo die 70A (or an integrated silicon photonic device) that integrates the optical redistribution structure 40 into the silicon photonic structure including the photonic die 20 and the electronic die 30.

According to some embodiments of the present disclosure, functional tests may be performed on the photonic die 20, the electronic die 30, and the optical fan-out die to ascertain whether the dies are known good dies (KGDs). Thus, only the dies that are KGDs undergo subsequent processing to be packaged, and the dies that fail the tests are not packaged. Therefore, the yield can be increased, and the cost can be reduced.

In addition, according to some embodiments of the present disclosure, the dummy dies 65 can not only define the space for disposing the optical fan-out die but also fix the relative position between the optical fan-out die and the photonic die 20, so as to ensure the alignment between the optical coupling layers 410 and the optical waveguides 210. Therefore, an accurate and stable alignment between the optical coupling layers 410 and the optical waveguides 210 can be provided, and thus the optical coupling efficiency can be improved.

Moreover, according to some embodiments of the present disclosure, the dielectric layer 61 combined with the electronic die 30 and the dummy die 30D may provide a planarized supporting surface. Therefore, the dummy die 30D further provides a structural stress balance for disposing the optical redistribution structure 40, and thus the structural reliability of the semiconductor package 2A is improved.

FIG. 2D is a top view of a semiconductor package 2D according to one or more embodiments of the present disclosure. FIG. 2E is a cross-sectional view of a semiconductor package 2D according to one or more embodiments of the present disclosure. In some embodiments, FIG. 2E is a cross-section along a line 2E-2E’ in FIG. 2D. In some embodiments, FIG. 2B is a cross-section along a line 2B-2B’ in FIG. 2D. The semiconductor package 2D illustrated in FIGS. 2D-2E is similar to the semiconductor package 2A illustrated in FIGS. 2A-2C, and the differences therebetween are described as follows.

In some embodiments, the semiconductor package 2D further includes dummy strips 450. In some embodiments, the dummy strips 450 are disposed next to the photonic die 20. In some embodiments, the dummy strips 450 are spaced apart from one another by a plurality of spacings that are substantially aligned with the optical waveguides 210. In some embodiments, the optical coupling layers 410 are disposed in the spacings. In some embodiments, the optical coupling layers 410 and the dummy strips 450 are or include dummy dies formed of different materials. In some embodiments, the dielectric layer 64 covers the optical coupling layers 410 and the dummy strips 450.

In some embodiments, the dielectric layers 61, 62, 63, and 64 cover or encapsulate the photonic die 20, the electronic die 30, and the optical redistribution structure 40 (or the optical fan-out structure) to form a combo die 70A’ (or an integrated silicon photonic device) that integrates the optical redistribution structure 40 into the silicon photonic structure including the photonic die 20 and the electronic die 30.

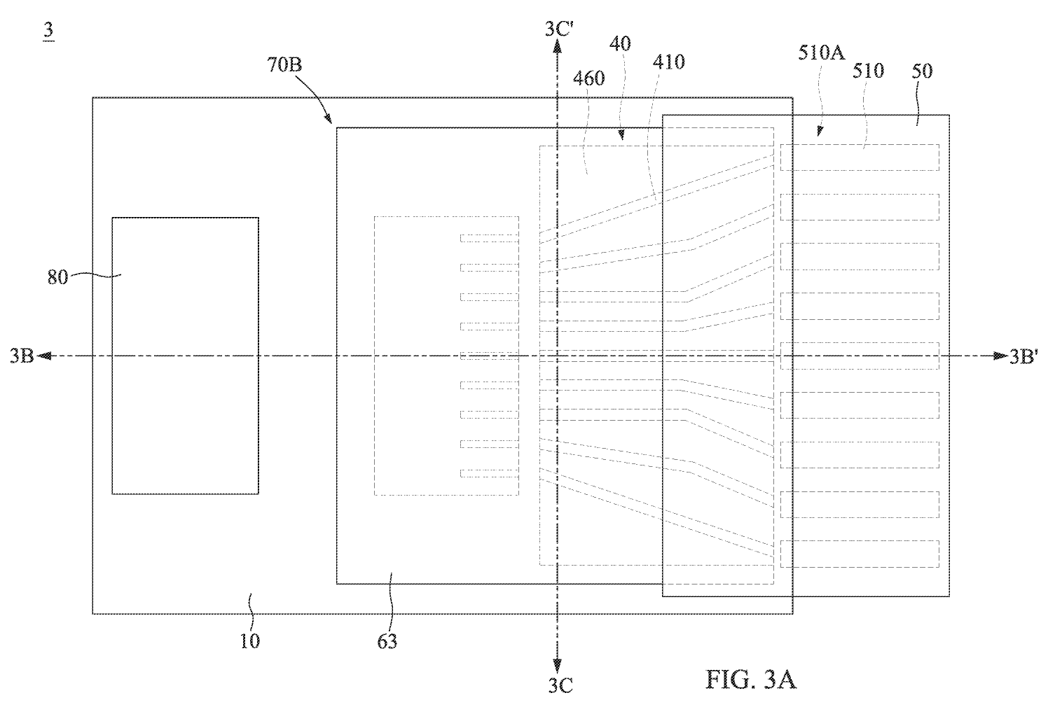

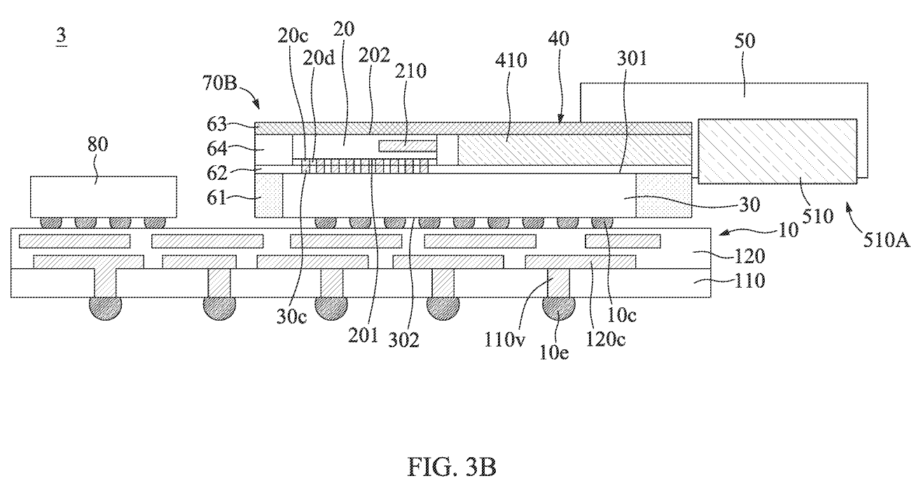

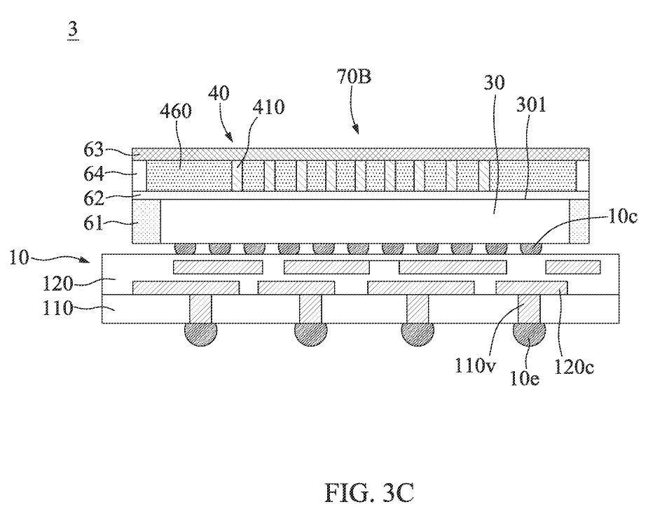

FIG. 3A is a top view of a semiconductor package 3 according to one or more embodiments of the present disclosure. FIG. 3B is a cross-sectional view of a semiconductor package 3 according to one or more embodiments of the present disclosure. FIG. 3C is a cross-sectional view of a semiconductor package 3 according to one or more embodiments of the present disclosure. In some embodiments, FIG. 3B is a cross-section along a line 3B-3B’ in FIG. 3A, and FIG. 3C is a cross-section along a line 3C-3C’ in FIG. 3A. The semiconductor package 3 illustrated in FIGS. 3A-3C is similar to the semiconductor package 1 illustrated in FIGS. 1A-1C, and the differences therebetween are described as follows.

In some embodiments, the optical redistribution structure 40 further includes a gap-fill dielectric 460 between the optical coupling layers 410. In some embodiments, the optical coupling layers 410 include semiconductor strips, e.g., silicon strips. In some embodiments, the dielectric layer 63 (or the protective layer) covers the optical coupling layers 410, the gap-fill dielectric 460, and the dielectric layer 64 (or the gap-fill dielectric).

In some embodiments, the dielectric layers 61, 62, 63, and 64 cover or encapsulate the photonic die 20, the electronic die 30, and the optical redistribution structure 40 (or the optical fan-out structure) to form a combo die 70B (or an integrated silicon photonic device) that integrates the optical redistribution structure 40 into the silicon photonic structure including the photonic die 20 and the electronic die 30.

According to some embodiments of the present disclosure, the optical coupling layers 410 are semiconductor strips that are manufactured by photolithography and etching processes. Therefore, the profiles of the semiconductor strips can be made with various different shapes (e.g., curved strips bending toward various directions) according to applications, thus the optical coupling layers 410 can fan-out the optical coupling paths effectively within a limited area.

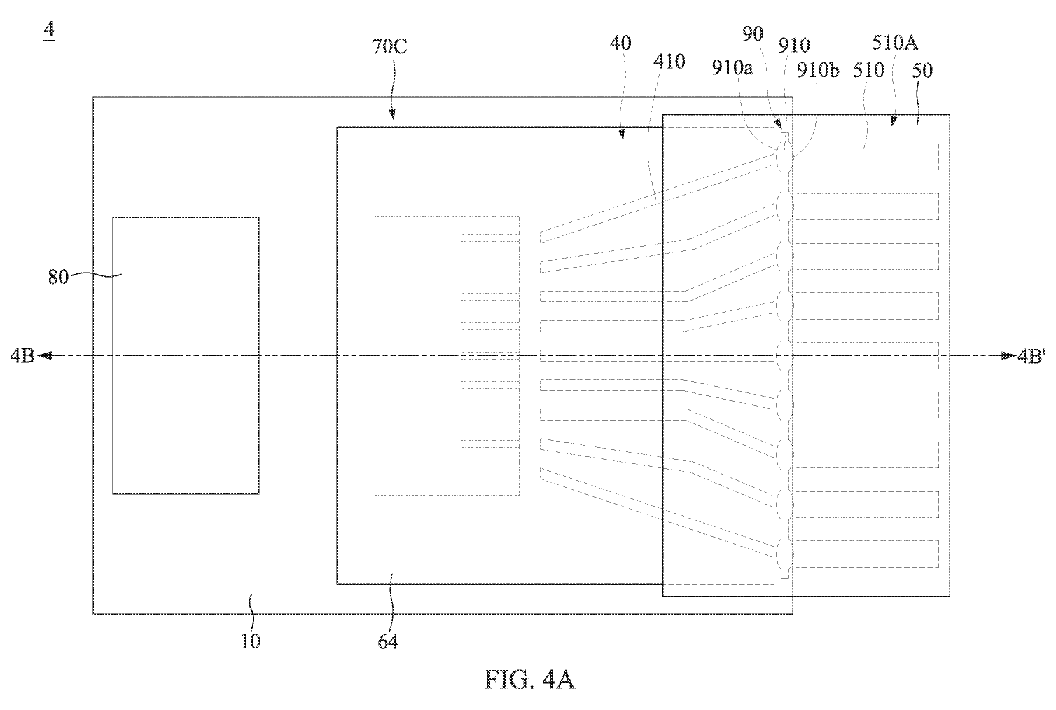

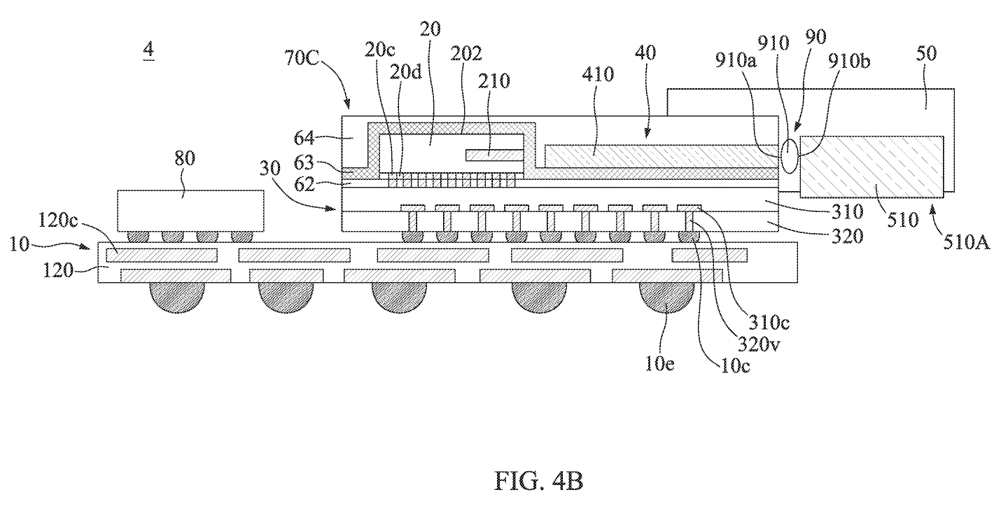

FIG. 4A is a top view of a semiconductor package 4 according to one or more embodiments 4 of the present disclosure. FIG. 4B is a cross-sectional view of a semiconductor package according to one or more embodiments of the present disclosure. In some embodiments, FIG. 4B is a cross-section along a line 4B-4B’ in FIG. 4A. The semiconductor package 4 illustrated in FIGS. 4A-4B is similar to the semiconductor package 1 illustrated in FIGS. 1A-1C, and the differences therebetween are described as follows.

In some embodiments, the semiconductor package 4 further includes a lens structure 90 between the optical redistribution structure 40 and the optical module 510A. In some embodiments, the lens structure 90 is configured to focus lights or optical signals transmitted from the optical fibers 510 to the optical coupling layers 410. In some embodiments, the lens structure 90 is configured to focus lights or optical signals transmitted from the optical coupling layers 410 to the optical fibers 510. In some embodiments, the lens structure 90 includes a plurality of lenses 910 each aligned with an optical fiber 510 and an optical coupling layer 410. In some embodiments, the lens 910 includes a curved surface 910a facing the optical coupling layer 410 and a curved surface 910b facing the optical fiber 510.

In some embodiments, the dielectric layers 61, 62, 63, and 64 cover or encapsulate the photonic die 20, the electronic die 30, and the optical redistribution structure 40 (or the optical fan-out structure) to form a combo die 70C (or an integrated silicon photonic device) that integrates the optical redistribution structure 40 into the silicon photonic structure including the photonic die 20 and the electronic die 30.

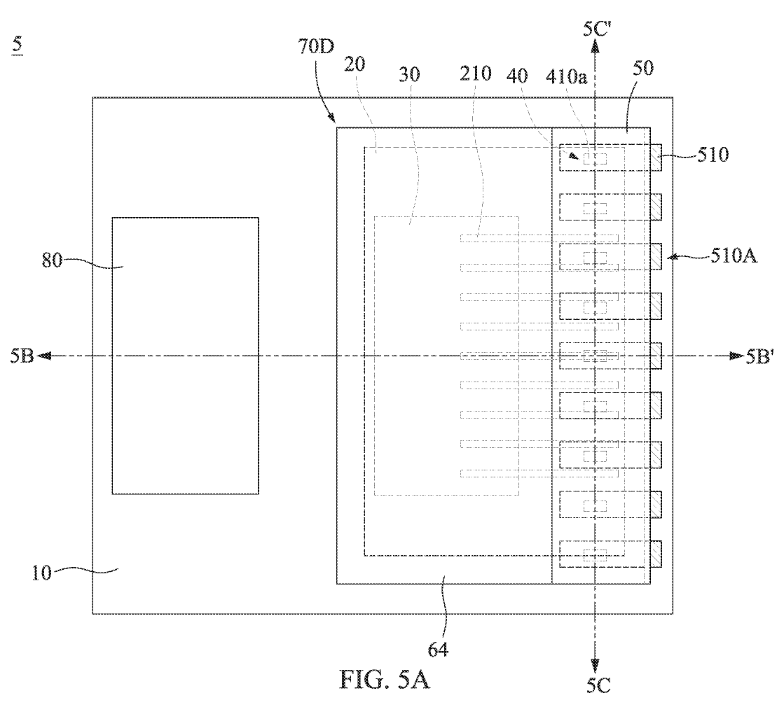

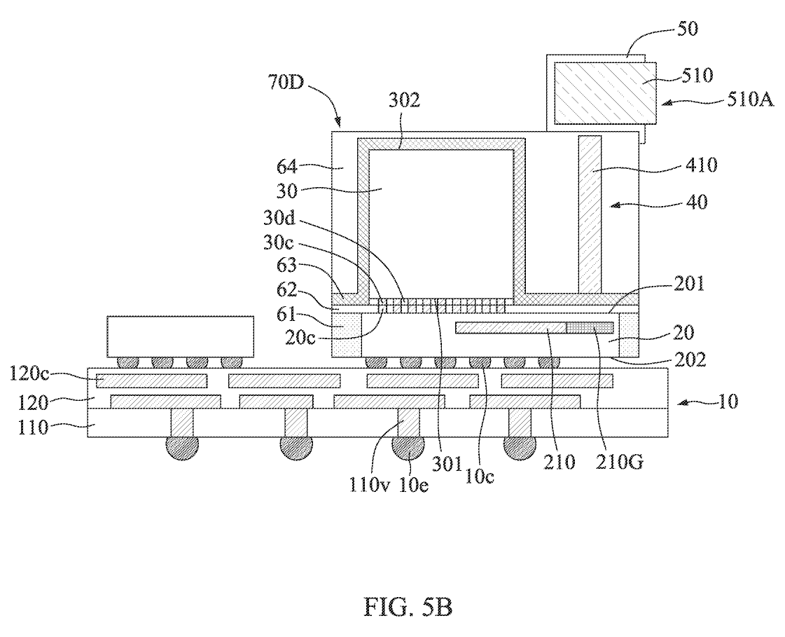

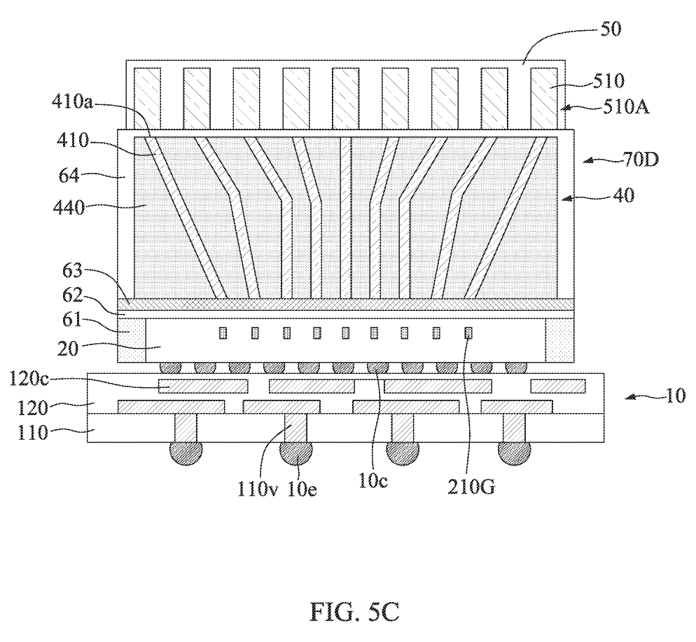

FIG. 5A is a top view of a semiconductor package 5 according to one or more embodiments of the present disclosure. FIG. 5B is a cross-sectional view of a semiconductor package 5 according to one or more embodiments of the present disclosure. FIG. 5C is a cross-sectional view of a semiconductor package 5 according to one or more embodiments of the present disclosure. In some embodiments, FIG. 5B is a cross-section along a line 5B-5B’ in FIG. 5A, and FIG. 5C is a cross-section along a line 5C-5C’ in FIG. 5A. The semiconductor package 5 illustrated in FIGS. 5A-5C is similar to the semiconductor package 2A illustrated in FIGS. 2A-2C, and the differences therebetween are described as follows.

In some embodiments, the photonic die 20 further includes grating couplers 210G. In some embodiments, each of the optical waveguides 210 is optically coupled to a respective grating coupler 210G. The optical waveguides 210 are configured to optically couple to the optical coupling layers 410 through the grating couplers 210G.

In some embodiments, the electronic die 30 and the optical redistribution structure 40 (or the optical fan-out die) are stacked over the photonic die 20. In some embodiments, the optical coupling layers 410 extend in a direction substantially perpendicular to a top surface (or the active surface 201) of the photonic die 20 and are configured to optically couple to the grating couplers 210G of the photonic die 20.

In some embodiments, the electronic die 30 is bonded to the photonic die 20 through hybrid bonding. In some embodiments, the dielectric layer 62 is formed on a surface of the photonic die 20, and the conductive features 20c are formed within the dielectric layer 62. In some embodiments, the electronic die 30 includes electrical connectors 30c and a dielectric layer 30d. In some embodiments, the dielectric layer 62 is bonded to the dielectric layer 30d through fusion bonding, and the electrical connectors 30c are bonded to the conductive features 20c through metal-to-metal direct bonding. In some embodiments, the dielectric layer 63 (or the protective layer) covers the electronic die 30, and the dielectric layer 64 (or the gap-fill dielectric) covers the optical fan-out die and the dielectric layer 63.

In some embodiments, the dielectric layers 61, 62, 63, and 64 cover or encapsulate the photonic die 20, the electronic die 30, and the optical redistribution structure 40 (or the optical fan-out structure) to form a combo die 70D (or an integrated silicon photonic device) that integrates the optical redistribution structure 40 into the silicon photonic structure including the photonic die 20 and the electronic die 30.

According to some embodiments of the present disclosure, the optical fan-out die is disposed next to the electronic die 30 and the photonic die 20 in an arrangement to allow the optical coupling layers 410 to vertically align with the optical waveguides 210 of the photonic die 20. Therefore, the optical fan-out die is arranged so as to allow the optical coupling layers 410 to extend vertically and optically couple to the grating couplers 210G from upwards, and thus the x-y plane area of the package can be reduced.

In addition, according to some embodiments of the present disclosure, the optical redistribution structure 40 is an optical fan-out die which can be disposed by a pick-and-place process, and thus the optical fan-out die can be placed in various arrangements according to the applications. Therefore, the flexibility of the arrangements of the optical coupling between the photonic die 20 and the optical module 510A can be increased.

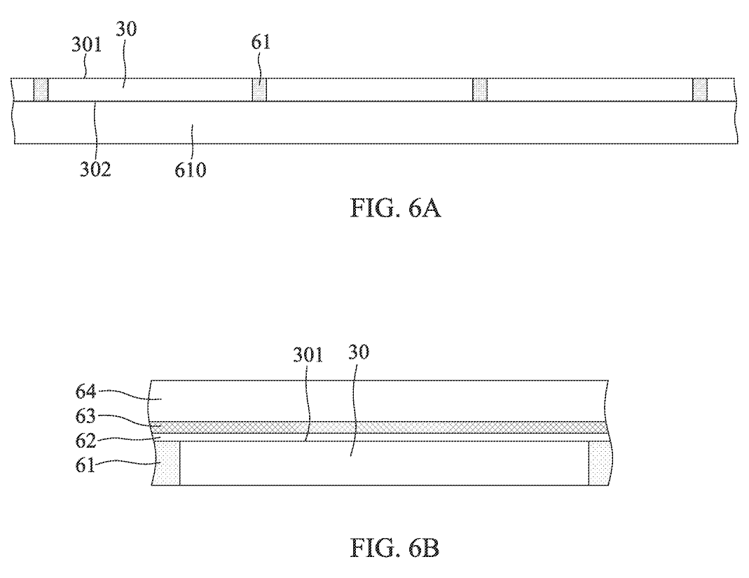

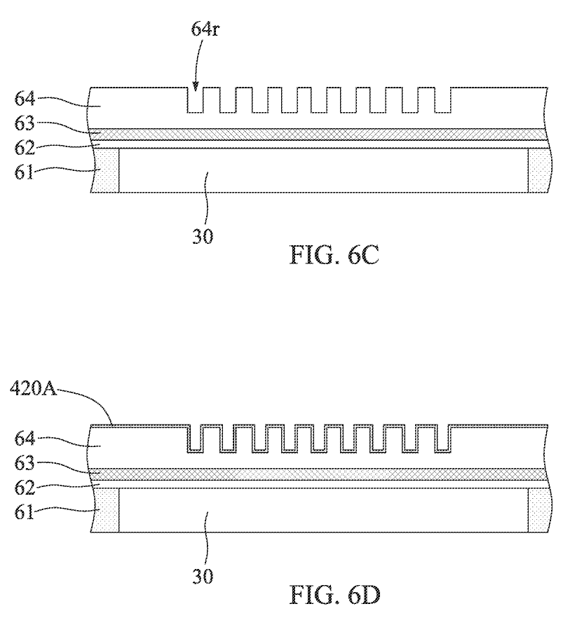

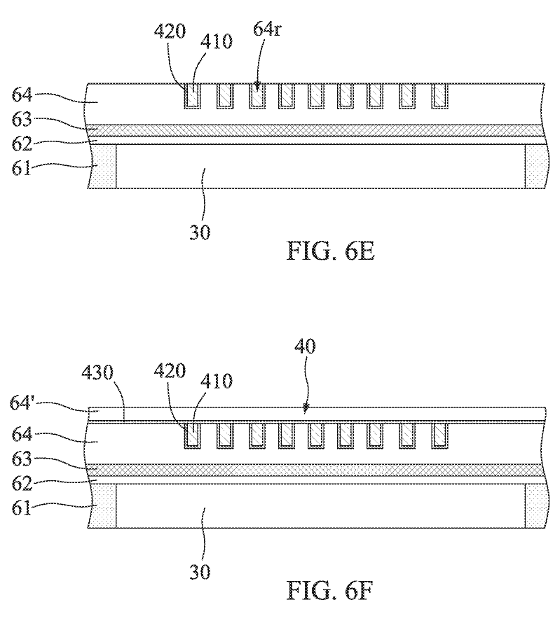

FIGS. 6A to 6F are schematic drawings illustrating a method for forming a semiconductor package 1 according to one or more embodiments of the present disclosure.

Referring to FIG. 6A, electronic integrated circuits of electronic dies 30 may be formed over a carrier 610, and a dielectric layer 61 may be formed to cover the electronic dies 30. The carrier 610 may be a semiconductor wafer, e.g., a silicon wafer. In some embodiments, the electronic dies 30 and the dielectric layer 61 may be thinned, e.g., by a planarization process, to expose active surfaces 301 of the electronic dies 30 from the dielectric layer 61. The back surfaces 302 of the electronic dies 30 may face the carrier 610.

Referring to FIG. 6B and FIG. 1B, a dielectric layer 62 may be formed over the electronic dies 30 and the dielectric layer 61 and surrounding the electrical connectors 30c, photonic dies 20 may be hybrid-bonded to the electronic dies 30, and the dielectric layers 63 and 64 may be formed over the photonic dies 20 and the dielectric layer 62. Please be noted that the carrier 610 is omitted from FIG. 6B to FIG. 6H for clarity.

Referring to FIG. 6C, a plurality of trenches 64r may be formed to be recessed from a top surface of the dielectric layer 64 and substantially aligned with the optical waveguides 210 of the photonic dies 20. The trenches 64r may be formed by etching.

Referring to FIG. 6D, a reflective liner material 420A may be formed on sidewalls of the trenches 64r and the top surface of the dielectric layer 64.

Referring to FIG. 6E, an optical coupling material may be filled in the trenches 64r to form the optical coupling layers 410. In some embodiments, a planarization process may be performed to remove portions of the reflective liner material 420A on the top surface of the dielectric layer 64 to form a plurality of reflective liners 420. The planarization process may be or include a chemical mechanical polish (CMP) process.

Referring to FIG. 6F, a reflective cap layer 430 may be formed over and contacting the dielectric layer 63 and the optical coupling layers 410. In some embodiments, a dielectric layer 64’ is further formed on the dielectric layer 63 and the optical coupling layers 410. In some embodiments, the dielectric layer 64’ is formed on and contacting the reflective cap layer 430.

Next, referring to FIGS. 1A-1E, the wafer-level structure formed from the step illustrated in FIG. 6F may be divided into integrated silicon photonic devices (e.g., the combo dies 70). In some embodiments, the integrated silicon photonic device and the semiconductor chip 80 are connected to the substrate 10, and the optical module 510A is connected to the integrated silicon photonic device through the holder 50. As such, the semiconductor package 1 may be formed.

In some embodiments, referring to FIGS. 2A-2C and FIGS. 6A and 6B, similar to processes illustrated in FIGS. 6A and 6B, dummy dies 30D and electronic integrated circuits of electronic dies 30 may be formed over a carrier 610, a dielectric layer 61 may be formed to surround the electronic dies 30 and the dummy dies 30D, a dielectric layer 62 may be formed over the electronic dies 30, the dummy dies 30D, and the dielectric layer 61 and surrounding the electrical connectors 30c, photonic dies 20 may be hybrid-bonded to the electronic dies 30, and a dielectric layer 63 (or a protective layer) may be formed over the photonic dies 20 and the dielectric layer 62 and covering the photonic die 20 and the electronic die 30. Next, referring to FIGS. 2A-2C, at least two dummy dies 65 may be disposed over the dielectric layer 63 to define a spacing over the electronic die 30, an optical fan-out die may be disposed in a spacing between the dummy dies 65 and next to the optical waveguides 210 of the photonic die 20, and then a dielectric layer 64 may be formed to cover the photonic die 20, the dielectric layer 63, the dummy dies 65, and the optical fan-out die to form integrated silicon photonic devices (e.g., the combo dies 70A).

In some embodiments, the optical fan-out die may be formed by the following steps: a cladding base 440 may be formed, a plurality trenches may be formed to be recessed from a top surface of the cladding base 440, and an optical coupling material may be filled in the trenches to form the optical coupling layers 410, so as to form the optical fan-out die (i.e., the optical redistribution structure 40) including the cladding base 440 and the optical coupling layers 410 within the cladding base 440.

Next, still referring to FIGS. 2A-2C, the above-mentioned wafer-level structure may be divided into integrated silicon photonic devices (e.g., the combo dies 70A). In some embodiments, the integrated silicon photonic device and the semiconductor chip 80 are connected to the substrate 10, and the optical module 510A is connected to the integrated silicon photonic device through the holder 50. As such, the semiconductor package 2A may be formed.

In some embodiments, referring to FIGS. 2D-2E and FIGS. 6A and 6B, similar to processes for forming the semiconductor package 2A, a plurality of dummy strips 450 may be disposed next to the photonic die 20, wherein the dummy strips 450 are spaced apart from one another by a plurality of spacings that are substantially aligned with the optical waveguides 210, and optical coupling layers 410 may be disposed in the spacings.

Next, still referring to FIGS. 2D-2E, the above-mentioned wafer-level structure may be divided into integrated silicon photonic devices (e.g., the combo dies 70A’). In some embodiments, the integrated silicon photonic device and the semiconductor chip 80 are connected to the substrate 10, and the optical module 510A is connected to the integrated silicon photonic device through the holder 50. As such, the semiconductor package 2D may be formed.

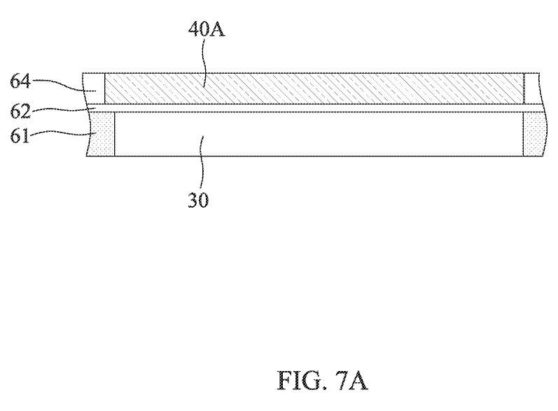

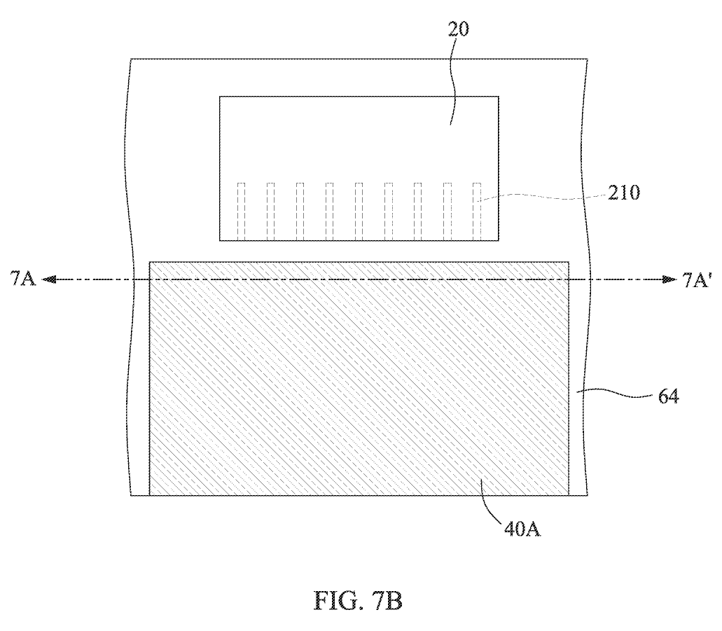

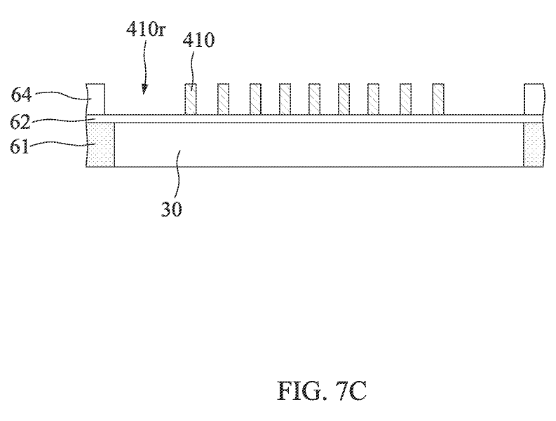

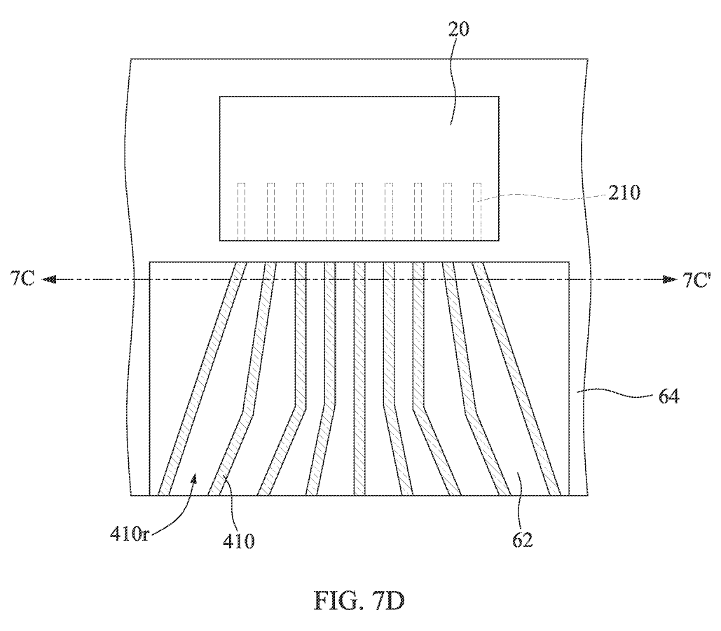

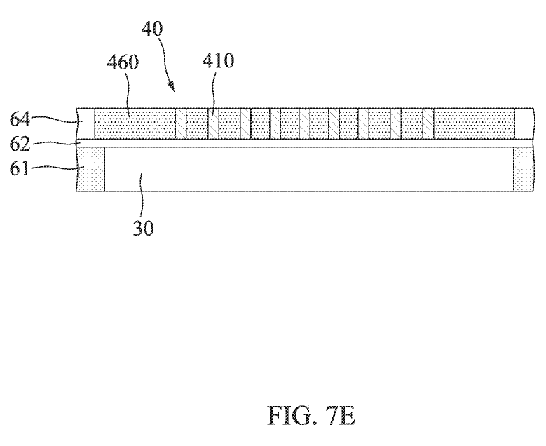

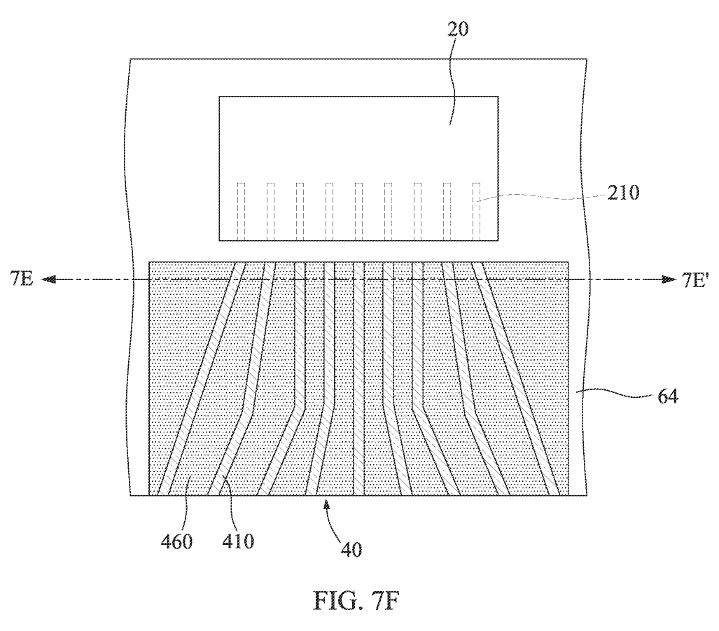

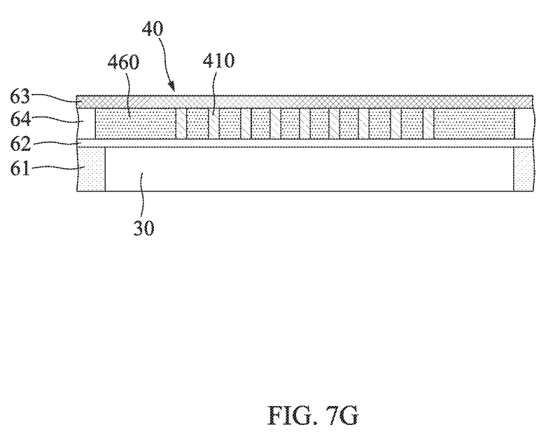

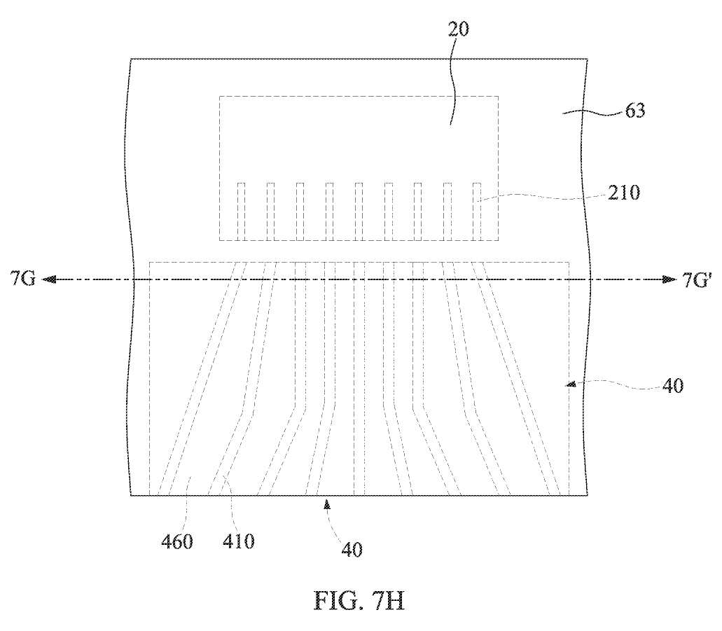

FIGS. 7A to 7H are schematic drawings illustrating a method for forming a semiconductor package 3 according to one or more embodiments of the present disclosure.

Similar to the processes illustrated in FIGS. 6A and 6B, electronic integrated circuits of electronic dies 30 may be formed over a carrier 610, a dielectric layer 61 may be formed to surround the electronic dies 30, a dielectric layer 62 may be formed over the electronic dies 30 and the dielectric layer 61 and surrounding the electrical connectors 30c, and photonic dies 20 may be hybrid-bonded to the electronic dies 30. Please be noted that the carrier 610 is omitted from FIG. 7A to 7H for clarity.

Referring to FIGS. 7A and 7B, FIG. 7A is a cross-section along a ling 7A-7A’ in FIG. 7B. A semiconductor substrate 40A may be disposed over the electronic die 30 and next to the photonic die 20. In some embodiments, the electronic die 30 is disposed on the dielectric layer 62, and a dielectric layer 64 may be formed over the photonic die 20 and the semiconductor substrate 40A. In some embodiments, the dielectric layer 64 may be thinned to surround the photonic die 20 and the semiconductor substrate 40A.

Referring to FIGS. 7C and 7D, FIG. 7C is a cross-section along a ling 7C-7C’ in FIG. 7D. The semiconductor substrate 40A may be patterned to form a plurality of semiconductor strips being the optical coupling layers 410. In some embodiments, the semiconductor substrate 40A may be patterned by an etching process. In some embodiments, a cavity 410r of the dielectric layer 64 is formed by the etching process.

Referring to FIGS. 7E and 7F, FIG. 7E is a cross-section along a ling 7E-7E’ in FIG. 7F. A gap-fill dielectric 460 may be formed between the optical coupling layers 410. In some embodiments, the gap-fill dielectric 460 is formed in the cavity 410r. At this stage, an optical redistribution structure 40 including the optical coupling layers 410 and the gap-fill dielectric 460 may be formed.

Referring to FIGS. 7G and 7H, FIG. 7G is a cross-section along a ling 7G-7G’ in FIG. 7H. A dielectric layer 63 (or a protective layer) may be formed over and contacting the gap-fill dielectric 460 and the optical coupling layers 410.

Next, referring to FIGS. 3A-3C, the wafer-level structure formed from the step illustrated in FIGS. 7G and 7H may be divided into integrated silicon photonic devices (e.g., the combo dies 70B). In some embodiments, the integrated silicon photonic device and the semiconductor chip 80 are connected to the substrate 10, and the optical module 510A is connected to the integrated silicon photonic device through the holder 50. As such, the semiconductor package 3 may be formed.

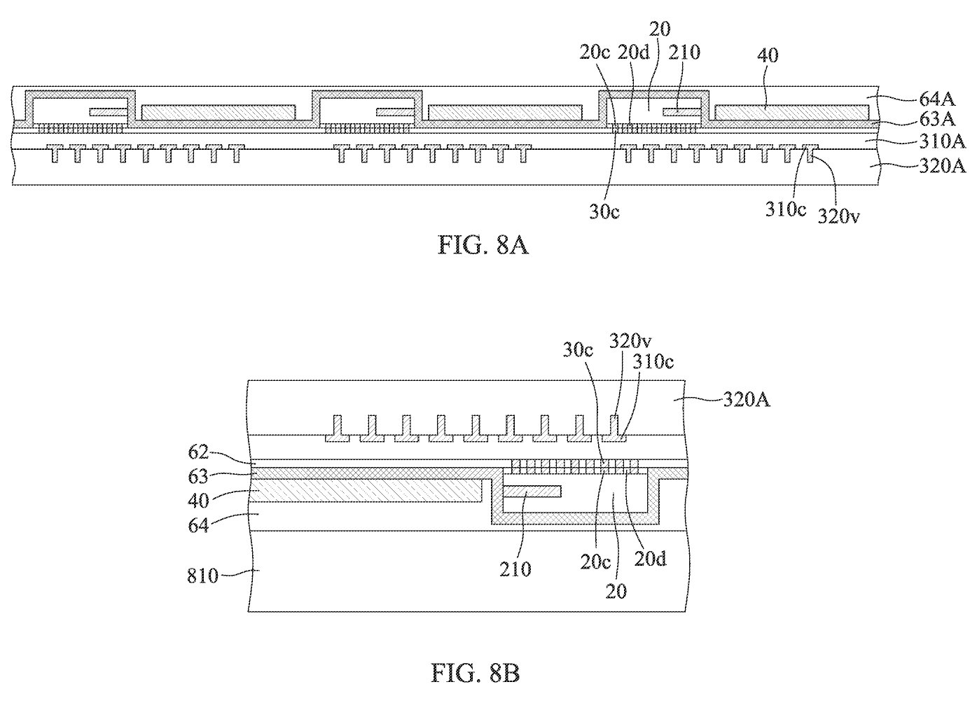

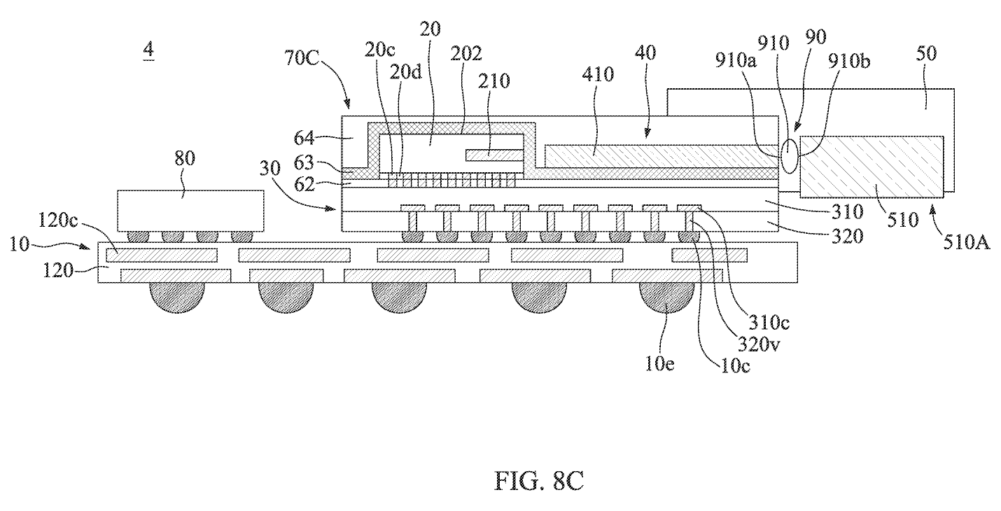

FIGS. 8A to 8C are schematic drawings illustrating a method for forming a semiconductor package 4 according to one or more embodiments of the present disclosure.

Referring to FIG. 8A, a semiconductor wafer 320A may be provided, conductive vias 320v (e.g., through silicon vias) may be formed within the semiconductor wafer 320A, conductive layers 310c may be formed on and connected to the conductive vias 320v, and a dielectric layer 310A may be formed to cover the conductive layers 310c. Next, referring to FIG. 8A and FIG. 4B, electronic integrated circuits may be formed over the dielectric layer 310A, photonic dies 20 may be hybrid-bonded to the electronic integrated circuits, a dielectric layer 63A may be formed to cover the photonic dies 20, optical redistribution structures 40 may be on the dielectric layer 63A, and a dielectric layer 64A may be formed to cover the dielectric layer 63A and the optical redistribution structures 40. The semiconductor wafer 320A may be a silicon wafer.

Referring to FIG. 8B, the structure formed from the step illustrated in FIG. 8B may be flipped over and disposed on a carrier 810, and the semiconductor wafer 320A may be thinned. In some embodiments, a grinding process or a chemical mechanical polish (CMP) process may be performed to thin the semiconductor wafer 320A until the conductive vias 320v are exposed by the thinned semiconductor wafer 320A.

Referring to FIG. 8C, the carrier 810 may be removed, and the wafer-level structure formed from the step illustrated in FIG. 8B may be divided into integrated silicon photonic devices (e.g., the combo dies 70C). In some embodiments, the integrated silicon photonic device and the semiconductor chip 80 are connected to the substrate 10, and the optical module 510A is connected to the integrated silicon photonic device through the holder 50. As such, the semiconductor package 4 may be formed.

Some embodiments of the present disclosure provide a method for forming a semiconductor package. The method includes the following steps: providing a photonic die and an electronic die; electrically connecting the photonic die to the electronic die; and forming an optical redistribution structure configured to optically couple to the photonic die, wherein forming the optical redistribution structure comprises forming a plurality of optical coupling layers having a pitch increasing away from the photonic die.

Some embodiments of the present disclosure provide a method for forming a semiconductor package. The method includes the following steps: providing a photonic die comprising a plurality of optical waveguides; electrically connecting the photonic die with an electronic die; and forming a plurality of optical coupling layers substantially aligned with the optical waveguides and having a spacing increasing away from the photonic die.

Some embodiments of the present disclosure provide a semiconductor package. The semiconductor package includes a photonic die, an electronic die, and an optical redistribution structure. The photonic die is electrically connected to the electronic die. The optical redistribution structure is configured to optically couple to the photonic die and includes a plurality of optical coupling layers. A pitch of the optical coupling layers increases away from the photonic die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor package, comprising:
providing a photonic die and an electronic die;
electrically connecting the photonic die to the electronic die; and
forming an optical redistribution structure configured to optically couple to the photonic die, wherein forming the optical redistribution structure comprises forming a plurality of optical coupling layers having a pitch increasing away from the photonic die.

2. The method of claim 1, further comprising:
forming a protective layer over the photonic die and the electronic die;
forming the optical coupling layers over the protective layer and substantially aligned with optical waveguides of the photonic die; and
forming a dielectric layer covering the optical coupling layers and the optical waveguides.

3. The method of claim 1, further comprising:
forming a protective layer over the photonic die and the electronic die;
forming a first dielectric layer on the protective layer;
forming a plurality of trenches recessed from a top surface of the first dielectric layer and substantially aligned with optical waveguides of the photonic die;
filling an optical coupling material in the trenches to form the optical coupling layers; and
forming a second dielectric layer on the first dielectric layer and the optical coupling layers.

4. The method of claim 3, further comprising:
forming a reflective liner material on sidewalls of the trenches prior to filling the optical coupling material; and
forming a reflective cap layer over and contacting the protective layer and the optical coupling layers.

5. The method of claim 1, wherein forming the optical redistribution structure comprises:
disposing a semiconductor substrate next to the photonic die;
patterning the semiconductor substrate to form a plurality of semiconductor strips being the optical coupling layers; and
forming a gap-fill dielectric between the optical coupling layers.

6. The method of claim 5, wherein forming the optical redistribution structure further comprises:
forming a dielectric layer to cover the semiconductor substrate and the photonic die prior to patterning the semiconductor substrate, wherein a cavity of the dielectric layer is formed by patterning the semiconductor substrate, and the gap-fill dielectric is formed in the cavity; and
forming a protective layer over and contacting the gap-fill dielectric and the optical coupling layers.

7. A method for forming a semiconductor package, comprising:
providing a photonic die comprising a plurality of optical waveguides;
electrically connecting the photonic die with an electronic die; and
forming a plurality of optical coupling layers substantially aligned with the optical waveguides and having a spacing increasing away from the photonic die.

8. The method of claim 7, wherein forming the optical coupling layers comprises:
forming a cladding base;
forming a plurality trenches recessed from a top surface of the cladding base;
filling an optical coupling material in the trenches to form an optical fan-out die comprising the cladding base and the optical coupling layers within the cladding base; and
disposing the optical fan-out die next to the optical waveguides.

9. The method of claim 8, further comprising forming a dielectric layer to cover the photonic die and the optical fan-out die.

10. The method of claim 8, further comprising:
forming a protective layer covering the photonic die and the electronic die;
disposing at least two dummy dies over the protective layer to define a spacing over the electronic die;
disposing the optical fan-out die in the spacing; and
forming a dielectric layer to cover the optical fan-out die and the dummy dies.

11. The method of claim 7, wherein forming the optical coupling layers comprises:
disposing a plurality of dummy strips next to the photonic die, wherein the dummy strips are spaced apart from one another by a plurality of spacings that are substantially aligned with the optical waveguides; and
disposing the optical coupling layers in the spacings.

12. The method of claim 7, wherein forming the optical coupling layers comprises:
disposing a semiconductor substrate next to the optical waveguides;
forming a dielectric layer to surround the semiconductor substrate and the photonic die;
etching the semiconductor substrate to form a plurality of semiconductor strips being the optical coupling layers in a cavity of the dielectric layer; and
forming a gap-fill dielectric in the cavity and between the optical coupling layers.

13. A semiconductor package, comprising:
a photonic die;
an electronic die electrically connected to the photonic die; and
an optical redistribution structure configured to optically couple to the photonic die and comprising a plurality of optical coupling layers having a pitch increasing away from the photonic die.

14. The semiconductor package of claim 13, wherein the photonic die comprises a plurality of optical waveguides configured to optically couple to an optical module through the optical coupling layers, a width of the optical coupling layers is greater than a width of the optical waveguides, and a minimum pitch of the optical coupling layers is substantially equal to a pitch of the optical waveguides.

15. The semiconductor package of claim 14, wherein the width of the optical coupling layers is less than a width of optical fibers of the optical module, and a maximum pitch of the optical coupling layers is substantially equal to a pitch of the optical fibers.

16. The semiconductor package of claim 13, wherein at least two of the optical coupling layers comprise curved profiles and bent toward different directions and away from each other.

17. The semiconductor package of claim 13, wherein the optical redistribution structure comprises an optical fan-out die comprising a cladding base, and the optical coupling layers are formed within the cladding base.

18. The semiconductor package of claim 13, wherein the electronic die and the optical redistribution structure are stacked over the photonic die, the optical coupling layers extend in a direction substantially perpendicular to a top surface of the photonic die and are configured to optically couple to grating couplers of the photonic die.

19. The semiconductor package of claim 13, further comprising a dielectric layer covering the optical redistribution structure and the photonic die.

20. The semiconductor package of claim 19, further comprising:
a protective layer between the dielectric layer and the photonic die;
a reflective cap layer over and contacting the protective layer and the optical coupling layers; and
a plurality of reflective liners between the optical coupling layers and the dielectric layer.
